(19) United States
(12) Patent Application Publication
(10) Pub. No.: US 2026/0022464 A1
(43) Pub. Date: Jan. 22, 2026

(54) SYSTEMS FOR MANUFACTURING SEMICONDUCTOR DEVICE AND RELEVANT METHODS

(71) Applicant: NANYA TECHNOLOGY CORPORATION, NEW TAIPEI CITY (TW)

(72) Inventor: SHIH-YUAN MA, NEW TAIPEI CITY (TW)

(21) Appl. No.: 18/775,170

(22) Filed: Jul. 17, 2024

(51) Int. Cl. C23C 16/458

(52) U.S. Cl. CPC C23C 16/4586; C23C 16/4584

(57) ABSTRACT

A system and a method for manufacturing a semiconductor device are provided. The system includes a processor, a processing reaction chamber body, a stage, and a heater. The processing reaction chamber body is configured to maintain a low-pressure environment, the system being configured to deposit a film on a wafer disposed in the low-pressure environment. The stage is configured to support the wafer during deposition of the film. The heater is electrically coupled to the processor and configured to control the temperature of the wafer by the stage. The stage includes an upper surface in contact with the wafer, and wherein the stage includes a plurality of heating lines electrically coupled to the heater for controlling the temperature in at least one area of the upper surface of the stage.

### TECHNICAL FIELD

The present disclosure relates to a system and method of manufacturing a semiconductor device, and more particularly, to a system and a method for depositing a film on a wafer.

### DISCUSSION OF THE BACKGROUND

To manufacture a semiconductor device, a wafer may undergo multiple photolithography processes, including at least photoresist, exposure, development, etching, deposition, diffusion, etc. During some of the processes, such as etching or deposition, the heating temperature will affect the critical dimension (CD) uniformity of a wafer. A means of adjusting the heating temperature on each area of a wafer is thus called for.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a system for manufacturing a semiconductor device. The system includes a processor, a processing reaction chamber body, a stage, and a heater. The processing reaction chamber body is configured to maintain a low-pressure environment, the system being configured to deposit a film on a wafer disposed in the low-pressure environment. The stage is configured to support the wafer during deposition of the film. The heater is electrically coupled to the processor and configured to control the temperature of the wafer by the stage. The stage includes an upper surface in contact with the wafer, wherein the stage includes a plurality of heating lines electrically coupled to the heater for controlling the temperature in at least one area of the upper surface of the stage.

One aspect of the present disclosure provides a system for manufacturing a semiconductor device. The system includes a processor, a processing reaction chamber body, and a stage. The processor is coupled to a non-transitory computer-readable medium storing computer-executable instructions. The processing reaction chamber body is configured to maintain a low-pressure environment within a space of the processing reaction chamber body. The stage is configured to hold a wafer disposed in the space of the processing reaction chamber body. The stage is electrically coupled to the processor and being configured to maintain the temperature of the wafer for a predetermined period. The temperature of an upper surface of the stage is controlled by a heater. The stage includes a plurality of heating lines for controlling the temperature in at least one area on the wafer disposed on the upper surface of the stage.

One aspect of the present disclosure provides a method for manufacturing a semiconductor device. The method includes providing a wafer, placing the wafer on a stage within a vacuum environment, depositing a film on the wafer, performing a photoresist process on the wafer, performing a soft bake process on the wafer to cure the photoresist, automatically capturing a plurality of local images on an upper surface of the wafer by an optical sensor unit and controlling the temperature in at least one area of an upper surface of the stage for a predetermined period based on a distortion image or warpage of the wafer calculated from the first plurality of local images, wherein the stage includes a plurality of heating lines for controlling the temperature in at least one area of the upper surface of the stage.

The embodiments of the present disclosure provide systems and methods for manufacturing a semiconductor device. The critical dimension (CD) uniformity of a wafer will be affected since the baking temperatures on each area on the surface of the wafer are different. In addition, the local heating temperature and heating speed of each area on the surface of the wafer will affect the deformation results and the CD uniformity of the film on the wafer. The CD uniformity or deformation on the wafer can be adjusted by controlling the temperature in each area of the wafer.

An average value of the critical dimension (CD) in each area of the wafer can be adjusted by controlling the temperature at each heating point (such as controlling the temperature at one heating point). In addition, the distortion image or warpage of the wafer can be adjusted by controlling the temperature at each heating point (such as controlling the temperature at one heating point). For example, in order to increase an average value of the CD in the area of the wafer on a heating point, the heating temperature at the area of the heating point can be decreased for a predetermined period.

The foregoing outlines rather broadly the features and technical advantages of the present disclosure in order that the detailed description of the disclosure that follows may be better understood. Additional features and advantages of the disclosure are described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It can also be appreciated by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a schematic diagram of a system for manufacturing a semiconductor device, in accordance with some embodiments of the present disclosure.

FIG. 1B is a schematic diagram of a computer device, in accordance with some embodiments of the present disclosure.

FIG. 1C is a schematic diagram of a system for manufacturing a semiconductor device, in accordance with some embodiments of the present disclosure.

FIG. 1D is a schematic diagram of a system for manufacturing a semiconductor device, in accordance with some embodiments of the present disclosure.

FIG. 2 is a schematic flowchart of an embodiment of a method of manufacturing a semiconductor device of a wafer, in accordance with some embodiments of the present disclosure.

FIG. 3 is a schematic flowchart of an embodiment of a method of manufacturing a semiconductor device of a wafer, in accordance with some embodiments of the present disclosure.

FIG. 4 is a top view of a stage in accordance with some embodiments of the present disclosure.

FIG. 5 is a top view of a stage in accordance with some embodiments of the present disclosure.

FIG. 6 is a schematic diagram of a stage, in accordance with some embodiments of the present disclosure.

FIG. 7 is a schematic diagram of a stage, in accordance with some embodiments of the present disclosure.

FIG. 8 is a diagram of average values of the critical dimension (CD) in different areas on a wafer from the top view.

FIG. 9A is a schematic flowchart of an embodiment of a method of manufacturing a semiconductor device of a wafer, in accordance with some embodiments of the present disclosure.

FIG. 9B is a schematic flowchart of an embodiment of a method of manufacturing a semiconductor device of a wafer, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10, 9, 8, 7, 6, 5, 4, 3, 2, or 1% of the reported numerical value.

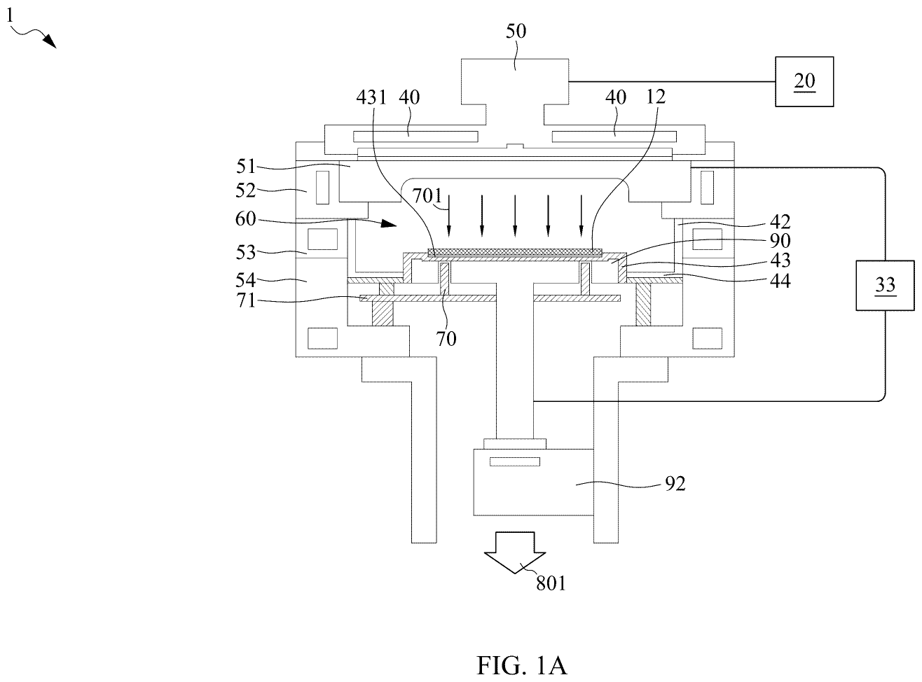

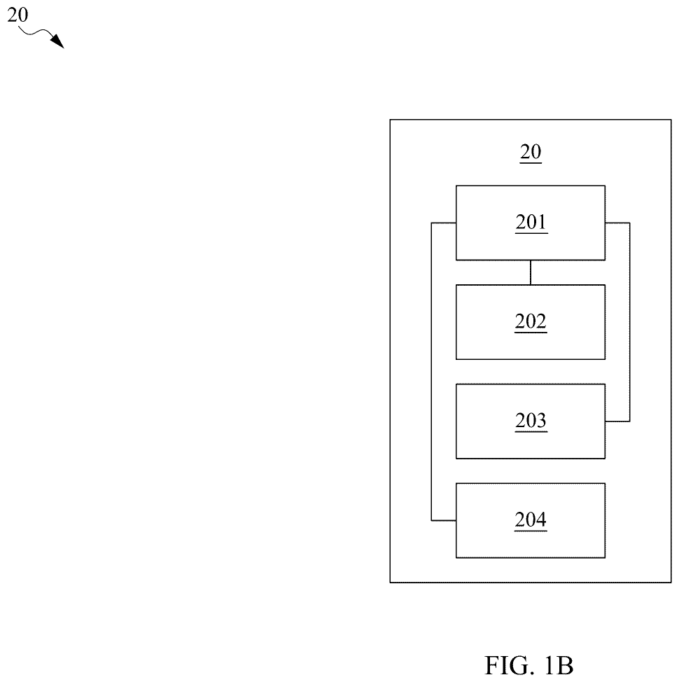

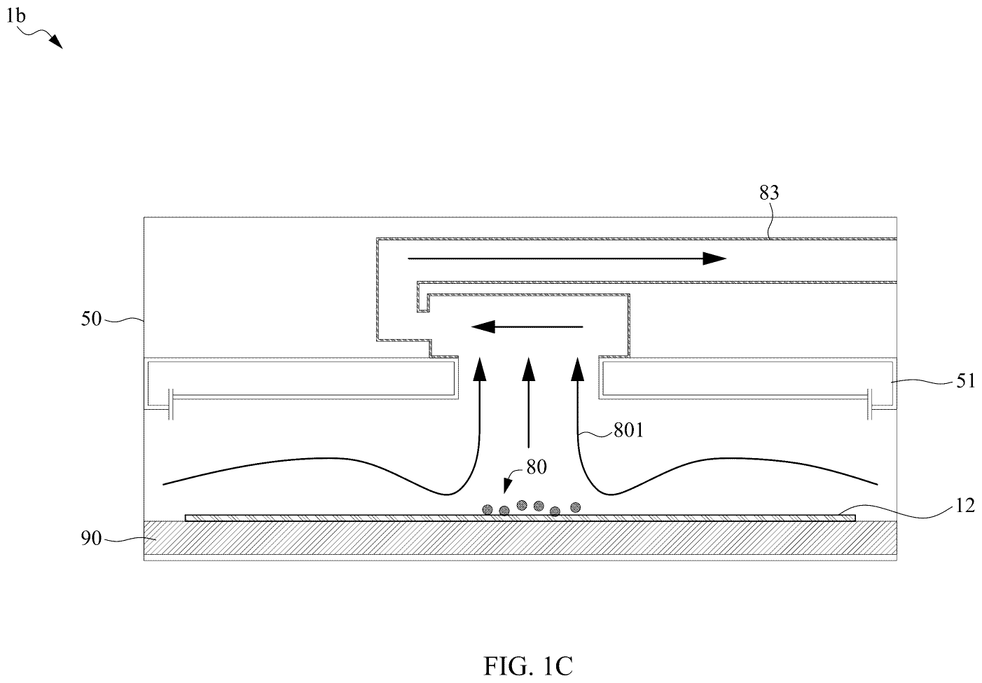

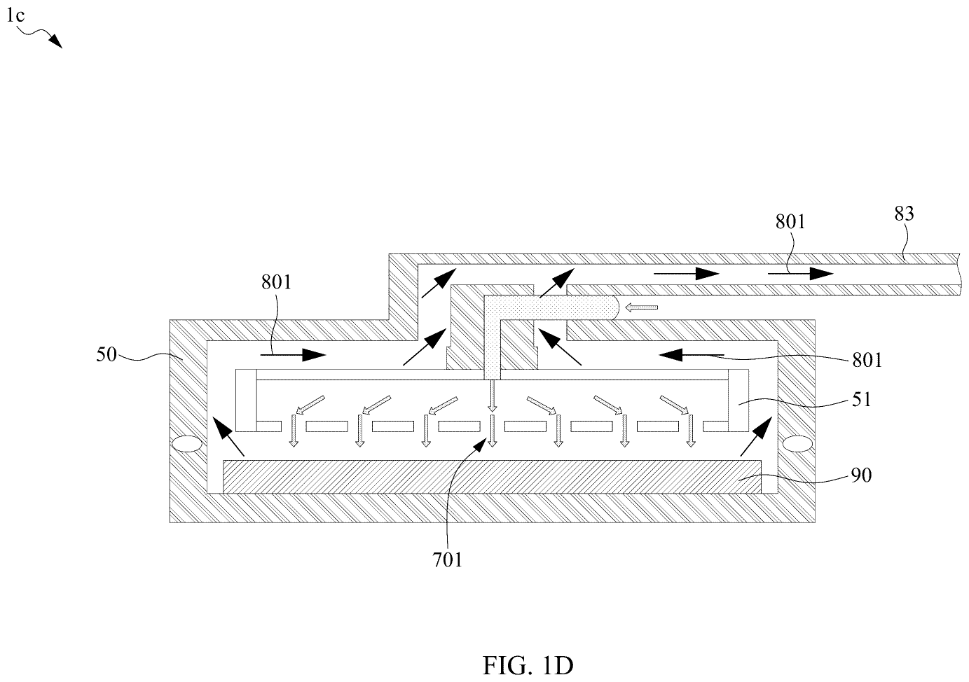

FIG. 1A is a schematic diagram of a system 1 for manufacturing a semiconductor device 12, in accordance with some embodiments of the present disclosure. The system 1 may be an automated robotic depositing film system, which may include a processor, photoresist unit, exposure unit, development unit, etc. Each unit may include corresponding apparatus.

Referring to FIG. 1A, the system 1 includes a stage 90, a computer device 20, and a processing reaction chamber body 50. In some embodiments, the processing reaction chamber body 50 is configured to maintain a low-pressure environment 60 during deposition of a film on the wafer 12. The processing reaction chamber body 50 is configured to maintain a low-pressure environment 60 within a space of the processing reaction chamber body 50. The system 1 is configured to deposit the film on a wafer 12 disposed in the low-pressure environment 60. In some embodiments, the deposition may include a plasma-enhanced chemical vapor deposition (PECVD) or chemical vapor deposition (CVD) process.

In some embodiments, the system 1 can include a stage 90 configured to support the wafer 12 during deposition of a film. In some embodiments, a heater 92 is electrically coupled to a processor 201 (shown in FIG. 1B) and configured to control the temperature of the wafer 12 by the stage 90. In some embodiments, the processor 201 is included in the computer device 20. In some embodiments, the stage 90 is configured to hold the wafer 12 disposed in the space of the processing reaction chamber body 50. The stage is electrically coupled to the processor 201 and configured to maintain the temperature of the wafer 12 for a predetermined period. The temperature of an upper surface of the stage 90 is controlled by the heater 92.

In some embodiments, an upper wall 52, a lower wall 53, a baffle cover 44, and a chamber housing 54 are configured to maintain a low-pressure environment (e.g. a vacuum environment). The negative pressure can be created by venting 801 through a vacuum pump (not shown).

The stage 90 can be configured to support the wafer 12 during deposition of the film. In some embodiments, the wafer 12 may be a semiconductor wafer. In some embodiments, the stage 90 has a susceptor cover 43 disposed thereon. The susceptor cover 43 has an upper surface 431. The bottom surface of the wafer 12 can be placed on the upper surface 431 of the susceptor cover 43 of the stage 90. In some embodiments, the upper surface 431 of susceptor cover 43 contacts the wafer.

In some embodiments, the stage 90 is configured to electrostatically fix the wafer 12 during deposition of the film. The stage 90 further includes lifter pins 70 configured to separate the wafer 12 from the stage 90. A lifter arm 71 is configured to move the lifter pins 70 to push the wafer 12 on the susceptor cover 43 thereby separating the wafer 12 from the stage 90.

In some embodiments, the system 1 can include a showerhead 51 above the stage 90. The system 1 includes a process gas delivery line for providing process gases, such as inert gases, precursors, reactants, and treatment reactants, for delivery to the system 1. In some embodiments, a showerhead 51 is included to distribute process gases within the processing reaction chamber body 50. In some embodiments, the stage 90 is configured to be moveable for rotation vertically.

In some embodiments, the showerhead 51 may be a dual-plenum or multi-plenum showerhead. In some embodiments, a dual-plenum showerhead may be a multi-plenum showerhead having three or more sets of holes. In some embodiments, the showerhead 51 and stage 90 electrically communicate with radio frequency (RF) power supply (plasma source) 33 for powering a plasma 701. In some embodiments, the plasma 701 is a capacitively-coupled plasma, and the plasma 701 may be generated by any suitable plasma source.

In some embodiments, RF power supply 33 may provide RF power of any suitable frequency. In some embodiments, RF power supply 33 may be configured to control high- and low-frequency RF power sources independently of one another. Example low-frequency RF powers may include, but are not limited to, frequencies between 200 kHz and 2000 kHz. Example high-frequency RF powers may include, but are not limited to, frequencies between 13.56 MHz and 80 MHz. Likewise, RF power supply 33 may be operated at any suitable power to form plasma 701. Examples of suitable powers include, but are not limited to, powers between 2500 W and 5000 W for a high-frequency plasma and powers between 0 W and 2500 W for a low-frequency plasma for a four-station multi-process tool including four 15-inch showerheads. RF power supply 33 may be operated at any suitable duty cycle. Examples of suitable duty cycles include, but are not limited to, duty cycles of between 5% and 90%.

In some embodiments, the stage 90 may be temperature controlled via the heater 92. Further, in some embodiments, the pressure control of the processing reaction chamber body 50 of the system 1 may be provided by any suitable pressure control device. In some embodiments, pressure control of the system 1 may also be adjusted by varying a flow rate of one or more gases introduced to the system 1. In some embodiments, the control of one or more process parameters may be provided locally (e.g., RF power may be controlled by a plasma controller communicating with the RF power supply 33.

FIG. 1B is a schematic diagram of a computer device 20, in accordance with some embodiments of the present disclosure. The computer device 20 may be capable of performing one or more procedures, operations, or methods of the present disclosure. The computer device 20 may be a host computer, a server computer, a client computer, a personal computer (PC), a tablet PC, a set-top box (STB), a personal digital assistant (PDA), a cellular telephone, or a smartphone. In some embodiments, the computer device 20 may be a host computer for controlling different apparatuses of the automated robotic depositing film system. For example, the computer device 20 may be configured to control the stage 90, heater 92, and processing reaction chamber body 50.

Referring to FIG. 1B, the computing device 20 includes a processor 201, input/output interface 202, communication interface 203, and memory 204. The input/output interface 202 is coupled with the processor 201. The input/output interface 202 allows the user to manipulate the computing device 20 to perform the procedures, operations, or methods of the present disclosure. The communication interface 203 is coupled with the processor 201. The communication interface 203 allows the computing device 20 to communicate with data outside the computing device 20, for example, receiving data including images and/or any essential features. A memory 204 may be a non-transitory computer readable storage medium. The memory 204 is coupled with the processor 201. The memory 204 is configured to store computer-executable instructions that can be executed by one or more processors (for example, the processor 201). In some embodiments, the processor 201 is coupled to a non-transitory computer-readable medium 204 which stores computer-executable instructions.

For example, upon execution of the program instructions stored on the memory 204, the program instructions cause performance of the one or more procedures, operations, or methods disclosed in the present disclosure. For example, the computing device 20 may execute the program instructions to cause the deposition of the film on the wafer 12 based on a distortion image or warpage of the wafer 12.

FIG. 1C is a schematic diagram of a system 1b for manufacturing a semiconductor device 12, in accordance with some embodiments of the present disclosure. Referring to FIG. 1C, system 1b is similar to system 1, and can include a showerhead 51 above the stage 90. The processing reaction chamber body 500K is configured to maintain a low-pressure environment during deposition of film on the wafer 12. The low-pressure environment can be created by venting 801 through an exhaust vent 83 to remove pollution particles 80 generated thereon during deposition on the wafer 12.

FIG. 1D is a schematic diagram of a system 1c for manufacturing a semiconductor device 12, in accordance with some embodiments of the present disclosure. Referring to FIG. 1D, the system 1c is similar to the system 1. The system 1c can include a showerhead 51 above the stage 90. The processing reaction chamber body 50 is configured to maintain a low-pressure environment during deposition of a film on a wafer. The low-pressure environment can be created by venting 801 through an exhaust vent 83. In some embodiments, the showerhead 51 and stage 90 electrically communicate with RF power supply for powering a plasma 701. In some embodiments, the plasma 701 is directed to the stage 90 to deposit a film on the wafer.

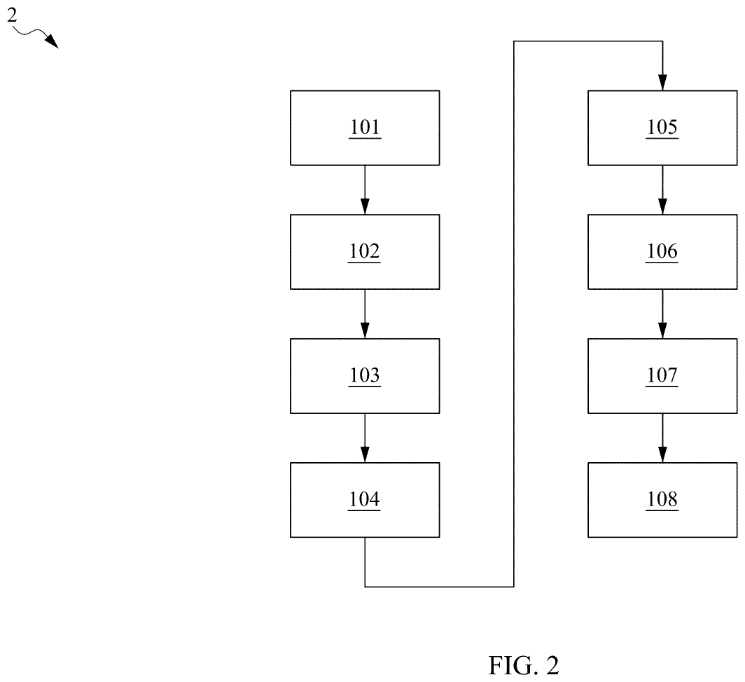

FIG. 2 is a schematic flowchart of an embodiment of a method 2 of manufacturing a semiconductor device of a wafer 12, in accordance with some embodiments of the present disclosure. The method 2 includes performing a vapor prime process on a wafer 12 (operation 101). In some embodiments, the wafer 12 includes Silicon (Si), glass, ceramic, lead frame, or other suitable insulating materials. In some embodiments, functional inorganic materials can be deposited on the wafer 12 by using chemical vapor deposition, physical vapor deposition or other desired approaches. The silicon wafer 12 with a native-oxide surface is used as a substrate for a thin-film deposition. The wafer 12 is treated with a hexamethyldisilazane (HMDS) vapor prime prior to resist deposition (process).

The method 2 includes performing a spin coating process (operation 102). In some embodiments, the spin coating includes a photo resist coating. In some embodiments, a material of the photo resist may be, for example, a photosensitive material, a positive polyimide, a positive or negative photoresist or other suitable materials.

The method 2 includes performing a soft bake process (operation 103). In some embodiments, the soft bake (post-apply bake “PAB”) process can remove the excess solvent from the wafer 12. In some embodiments, the soft bake process can be performed on the stage 90 in the processing reaction chamber body 50. In some embodiments, the photoresist on the wafer 12 are subjected to the PAB process on the stage 90 for 2-5 minutes at 90-150° C. In some embodiments, the operating temperature during the PAB process may be 90, 100, 120, or 130° C. The PAB process can bake or heat the wafer after applying photoresist on the wafer 12. If the baking time of PAB process is too long or the baking temperatures on various areas of the wafer are uneven, the critical dimension (CD) of different patterns made on the wafer 12 will be affected. The CD uniformity of the wafer 12 will be affected since the baking temperatures on each area on the surface of the wafer are different. In addition, the local heating temperature and heating speed of each area on the surface of the wafer will affect the deformation results and the CD uniformity of the film on the wafer 12. In some embodiments, the PAB process can be performed on the stage 90 in the processing reaction chamber body 50. In some embodiments, the local heating temperature of each area on the surface of the wafer during the PAB process can be controlled by the stage 90. The critical dimension (CD) of the photo resist in each area of the wafer 12 can be adjusted by controlling the temperature in each area of the wafer 12.

The method 2 includes performing an alignment and exposure (pattern transfer) process (operation 104). In some embodiments, a wafer 12 is exposed using UV light, EUV light, or other suitable light. The method 2 includes performing a post-exposure bake (PEB) process (operation 105). In some embodiments, the resist and wafer 12 are subjected to a post-exposure bake (PEB) on the stage 90 for 2-5 minutes at 90-200° C. In some embodiments, the operating temperature during the PEB process may be 90, 95, 100, 110, or 130° C. The operating temperature depends on the properties of the photo resist. If the baking temperatures during the PEB process on various areas of the wafer are uneven, the CD of different patterns made on the wafer 12 will be affected. The CD uniformity and deformation of the wafer 12 will be affected since the baking temperatures on each area on the surface of the wafer are different. Therefore, the local heating temperature and heating speed of each area on the surface of the wafer will affect the deformation results and the CD uniformity of the film on the wafer 12. In some embodiments, the PEB process can be performed on the stage 90 in the processing reaction chamber body 50. In some embodiments, the local heating temperature of each area on the surface of the wafer during the PEB process can be controlled by the stage 90.

The method 2 includes performing a develop process (operation 106). In some embodiments, the exposed film on the wafer 12 is dipped in 2-heptanone for 15 seconds and rinsed an additional 15 seconds with the same developer to form a negative tone image, i.e., unexposed portions of the coating were removed. The method 2 includes performing a hard bake process (operation 107). In some embodiments, a final 150° C. 2-minute hot bake is performed to complete the process. In some embodiments, the hard bake can be performed on the stage 90 in the processing reaction chamber body 50. In some embodiments, the local heating temperature of each area on the surface of the wafer during the hard bake process can be controlled by the stage 90.

The method 2 includes performing a developing inspect process (operation 108). The residual resist thicknesses of the exposed film can be measured by an optical sensor unit 40 or other suitable apparatuses.

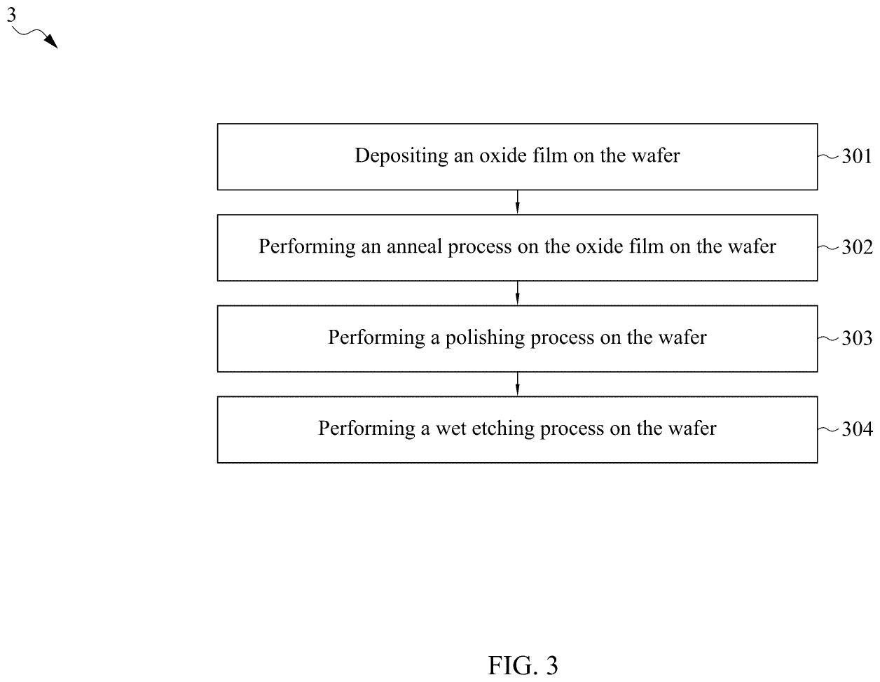

FIG. 3 is a schematic flowchart of an embodiment of a method 3 of manufacturing a semiconductor device of a wafer 12, in accordance with some embodiments of the present disclosure. The method 3 includes depositing an oxide film on the wafer 12 (operation 301). In some embodiments, the wafer 12 includes silicon (Si), glass, ceramic, lead frame, or other suitable insulating materials.

The method 3 includes performing an anneal process on the oxide film on the wafer 12 (operation 302). After the annealing, the wafer 12 may experience increased distortion or warpage on the film on the surface of the wafer 12. In some embodiments, the annealing may correspond to the soft bake process in operation 103 of FIG. 2. The annealing can be performed on the stage 90 in the processing reaction chamber body 50. In some embodiments, the local heating temperature of each area on the surface of the wafer during the annealing can be controlled by the stage 90.

The method 3 includes performing a polishing process on the wafer 12 (operation 303). In some embodiments, the polishing process includes a chemical mechanical planarization (CMP) polishing process. The method 3 includes performing a wet etching process on the wafer 12 (operation 304). After the wet etching process, the wafer 12 may experience increased distortion or warpage on the film on the surface of the wafer 12. After the etching process, a hard bake process may be performed on the wafer 12. The hard bake process may correspond to the hard bake process in operation 107 of FIG. 2.

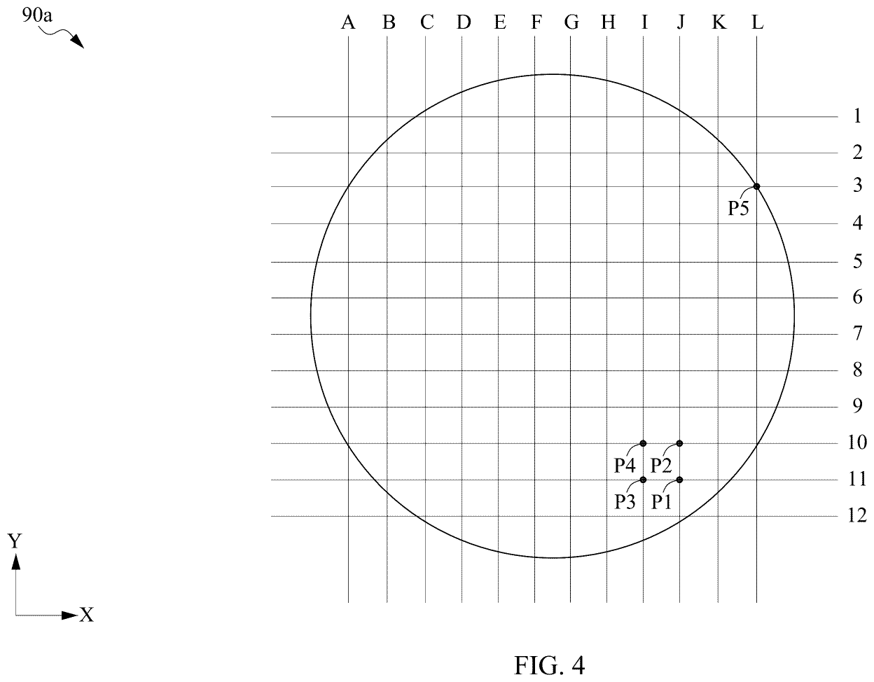

FIG. 4 is a top view of a stage 90a in accordance with some embodiments of the present disclosure. In some embodiments, the stage 90a includes a plurality of heating lines. The plurality of heating lines include lines A-L extending along a Y-axis and lines 1-12 along a X-axis. In some embodiments, the stage 90a is electrically coupled to the heater 92 for controlling the temperature in at least one area of the upper surface of the stage 90a. In some embodiments, the stage 90 includes a plurality of heating lines A-L and 1-12 for controlling the temperature in at least one area of the wafer 12 disposed on the upper surface of the stage 90a.

The plurality of heating lines include a first plurality of heating lines A-L extending along a first orientation (Y-axis) and a second plurality of heating lines 1-12 extending along a second orientation (X-axis). The X-axis is orthogonal to the Y-axis from a top view.

In some embodiments, each of the first plurality of heating lines A-L further includes, for example, a first plurality of heating points P1-P5. The temperature of each of the first plurality of heating points P1-P5 is controlled and maintained in a constant value by the heater 92 for a predetermined period. In some embodiments, each of the second plurality of heating lines 1-12 further includes, for example, a second plurality of heating points P1-P5. Each point of the second plurality of heating points P1-P5 respectively overlaps one point of the first plurality of heating points P1-P5. Each point of the second plurality of heating points is respectively located at an intersection between one of the second plurality of heating lines 1-12 and the first plurality of heating lines A-L. For example, point P2 of the second plurality of heating points is located at an intersection between the heating line 10 of the second plurality of heating lines 1-12 and the heating line J of the first plurality of heating lines A-L. In some embodiments, one heating point P5 of the first plurality of heating points is disposed on an edge of the upper surface of the stage 90a from the top view.

In some embodiments, one point P1 of the first plurality of heating points is maintained at a different temperature than another adjacent point P2 of the first plurality of heating points for a predetermined period. In some embodiments, one point P1 of the first plurality of heating points is maintained at the same temperature as one adjacent point P2 of the first plurality of heating points for a predetermined period. In some embodiments, an average value of the critical dimension (CD) in each area of the wafer 12 can be adjusted by controlling the temperature at each heating point (such as controlling the temperature at the heating point P1 or P2). In some embodiments, the distortion image or warpage of the wafer 12 can be adjusted by controlling the temperature at each heating point (such as controlling the temperature at the heating point P1 or P2). For example, in order to increase an average value of the CD in the area of the wafer 12 at the heating point P1, the heating temperature at the area of the point P1 can be decreased for a predetermined period. In some embodiments, the distortion image or warpage of the wafer 12 can be adjusted by controlling the temperature at different areas of the wafer 12. For example, if the distortion image or warpage at the area of the wafer 12 on the heating point P1 is high, the heating temperature corresponding to the heating point P1 can be decreased for a predetermined period.

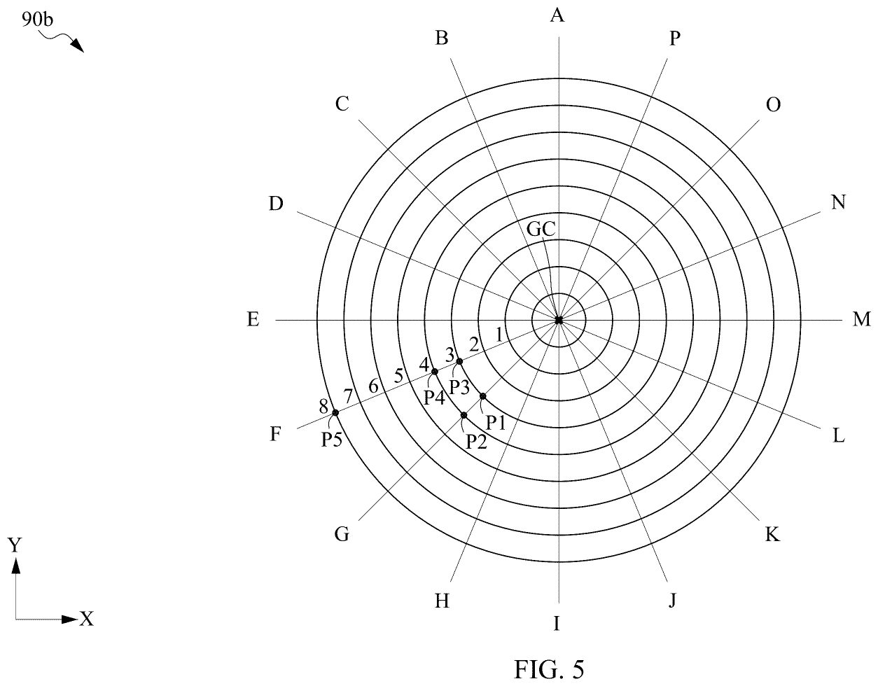

FIG. 5 is a top view of a stage 90b in accordance with some embodiments of the present disclosure. In some embodiments, the stage 90b includes a plurality of heating lines. The plurality of heating lines includes a first plurality of heating circle lines 1-8 surrounding a geometrical center GC of the upper surface of the stage 90b. Each of the first plurality heating circle lines 1-8 further includes, for example, a first plurality of heating points P1-P5. The temperature of each of the first plurality of heating points is controlled and maintained at a constant value by the heater 92 for a predetermined period. In some embodiments, each of the third plurality of heating circle lines 1-8 includes a different diameter measured from a geometrical center GC of the upper surface of the stage 90b. In some embodiments, each of the third plurality heating circle lines 1-8 further includes, for example, a third plurality of heating points P1-P5. Each point of the third plurality of heating points P1-P5 respectively overlaps one of the first plurality of heating points P1-P5.

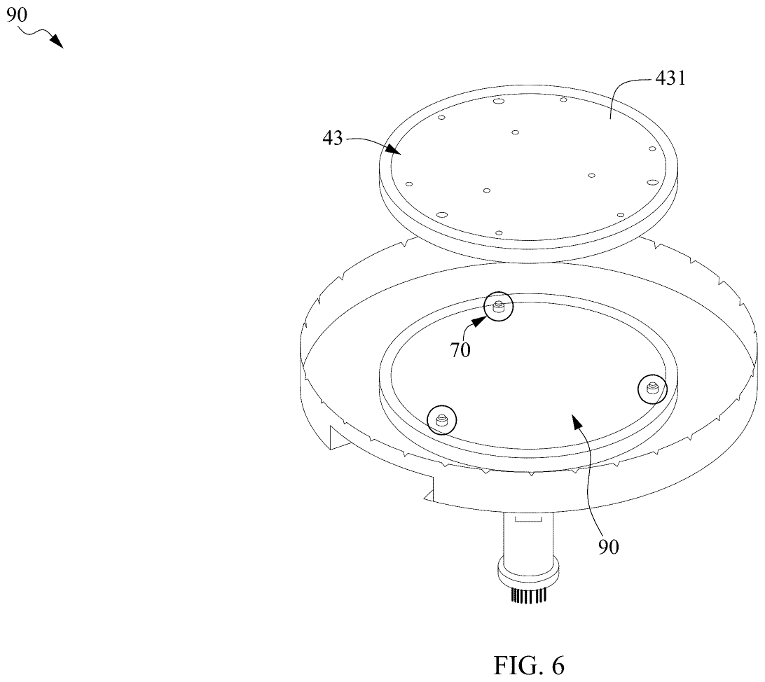

FIG. 6 is a schematic diagram of a stage 90, in accordance with some embodiments of the present disclosure. The stage 90 includes a susceptor cover 43 disposed thereon. The susceptor cover 43 has an upper surface 431. The bottom surface of the wafer 12 can be placed on the upper surface 431 of the susceptor cover 43 of the stage 90. In some embodiments, the upper surface 431 of the susceptor cover 43 contacts the wafer 12. The stage 90 further includes three lifter pins 70 configured to separate the wafer 12 from the stage 90. The lifter pins 70 can be moved to pass through a hole of the susceptor cover 43 to push the wafer 12 kept on the susceptor cover 43 thereby separating the wafer 12 from the stage 90.

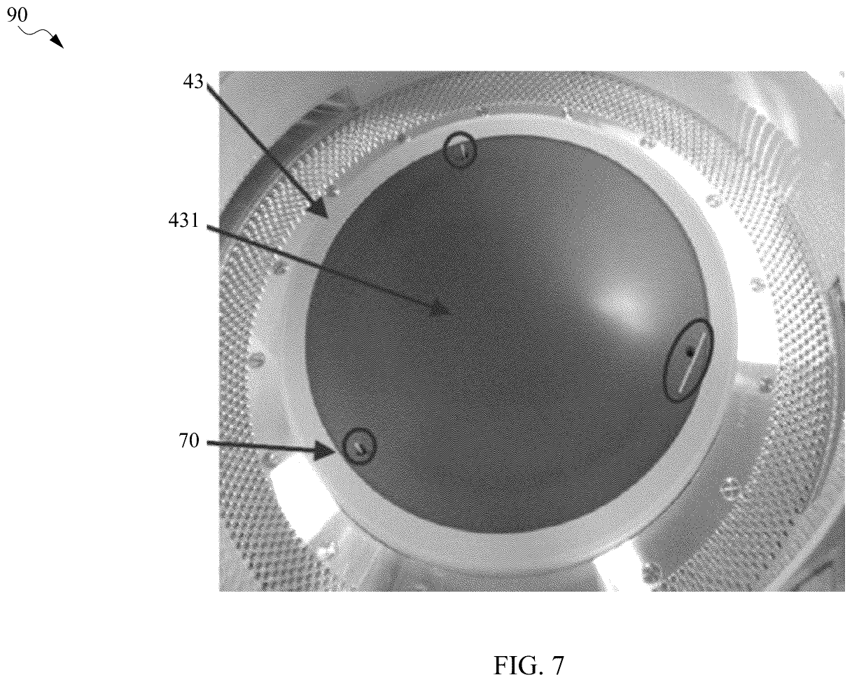

FIG. 7 is a schematic diagram of a stage 90, in accordance with some embodiments of the present disclosure. The stage 90 includes a susceptor cover 43 disposed thereon. The susceptor cover 43 includes three holes on the upper surface 431. The three lifter pins 70 are configured to move to pass through the holes of the susceptor cover 43 to push the wafer 12 kept on the susceptor cover 43. After releasing the wafer 12, the three lifter pins 70 can be moved down. After moving down, the final positions of the three lifter pins 70 are recessed from the upper surface 431 of the susceptor cover 43.

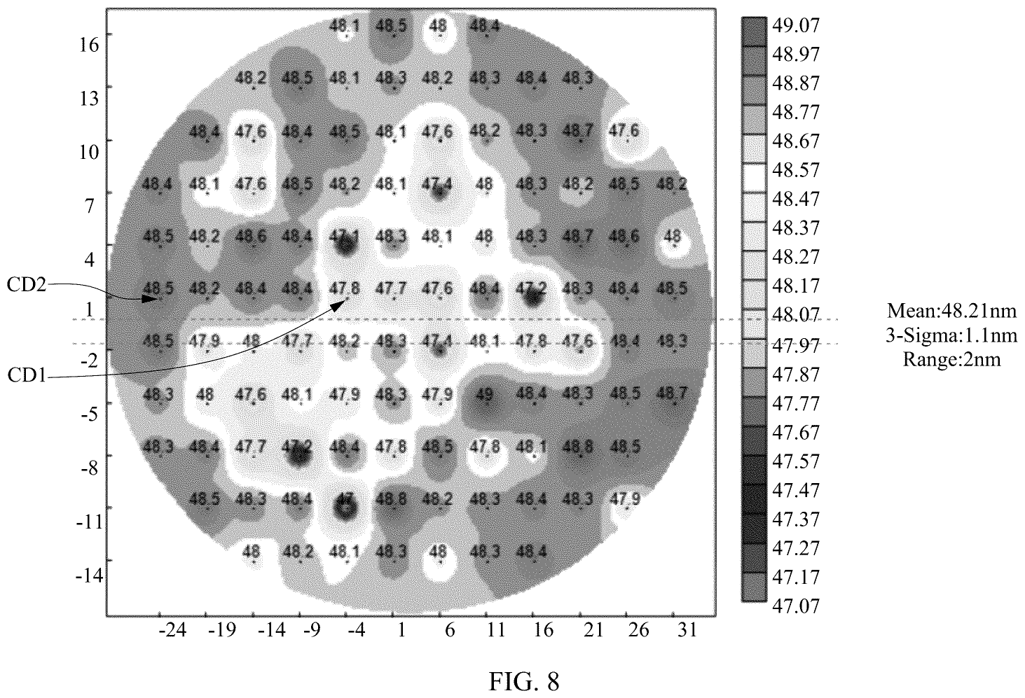

FIG. 8 is a diagram of average values of the critical dimension (CD) on different areas on a wafer 12 from the top view. In some embodiments, a point CD1 represents a measured average value of the CD on an area on the wafer 12. In some embodiments, the average value of the CD of the patterns formed at the point CD1 of the wafer 12 is 47.8 nanometer (nm). In some embodiments, the average value of the CD of the patterns formed at the point CD2 of the wafer 12 is 48.5 nm. In order to increase the average value of the CD of the wafer at the point CD1, the heating temperature at the area of the point CD1 can be decreased. In order to decrease the average value of the CD of the wafer at the point CD2, the heating temperature at the area of the point CD2 can be increased. In some embodiments, the different heating temperatures at the area of the points CD1 and CD2 can be controlled by the heater 92 for a predetermined period. In some embodiments, the different heating temperature at the area of the points CD1 and CD2 can be controlled through the heating points as described above on FIGS. 4 and 5. In some embodiments, the CD uniformity of the patterns formed at different areas of the wafer 12 can be adjusted by controlling the temperature at different areas of the wafer 12. In some embodiments, the distortion image or warpage of the wafer 12 can be adjusted by controlling the temperature at different areas of the wafer 12. If the distortion image or warpage at one area of the wafer 12 is high, the heating temperature in the one area of the wafer 12 can be decreased.

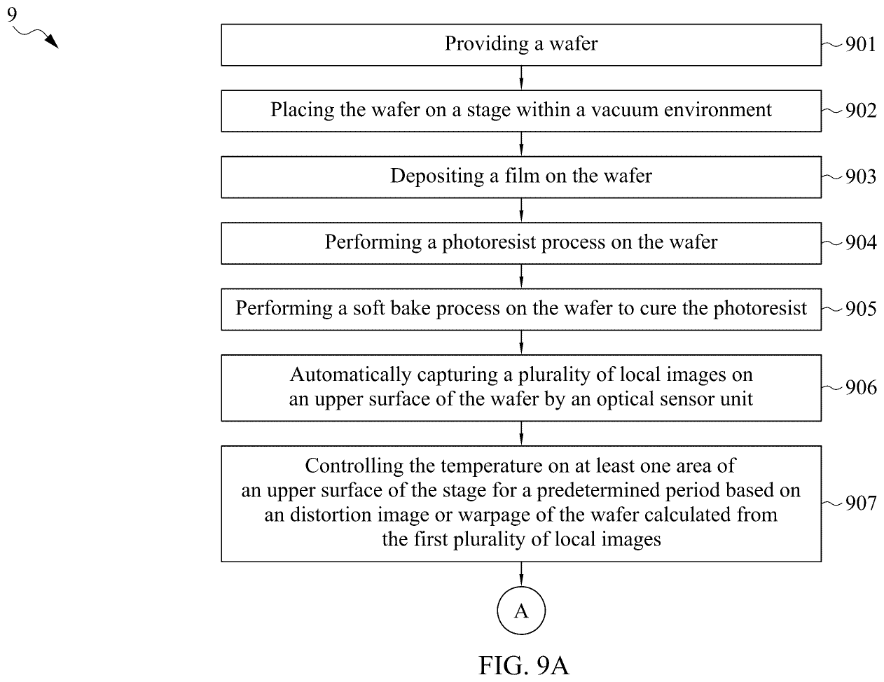

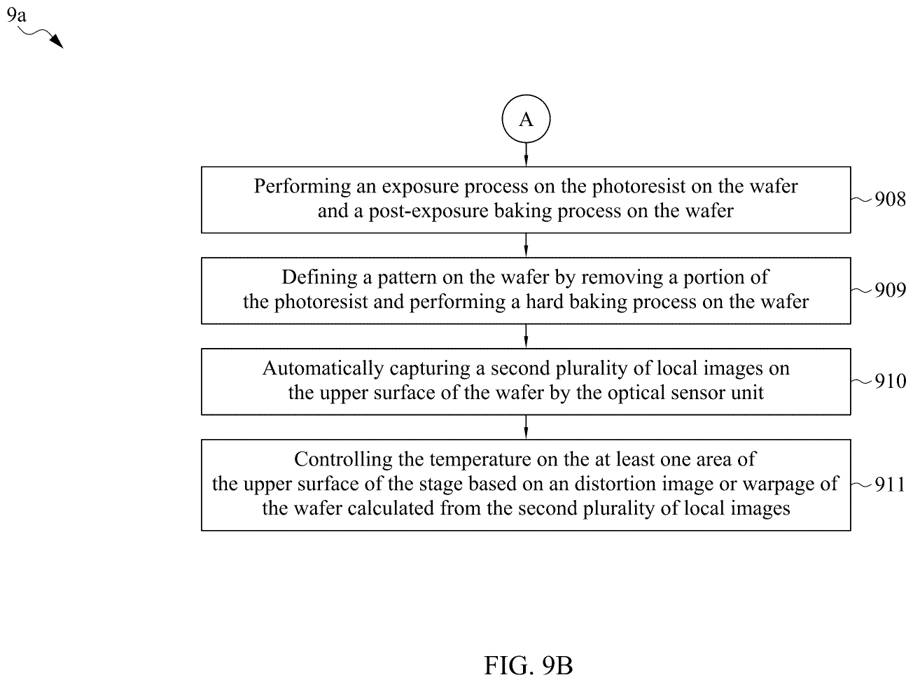

FIG. 9A is a schematic flowchart of an embodiment of a method 9 of manufacturing a semiconductor device of a wafer 12, in accordance with some embodiments of the present disclosure. The method 9 includes providing a wafer 12 (operation 901). The method 9 includes placing the wafer 12 on a stage 90 within a vacuum environment 60 (operation 902). The method 9 includes depositing a film on the wafer 12 (operation 903). The method 9 includes performing a photoresist process on the wafer 12 (operation 904). The method 9 includes performing a soft bake process on the wafer 12 to cure the photoresist (operation 905). The method 9 includes automatically capturing a plurality of local images on an upper surface of the wafer 12 by an optical sensor unit 40 (operation 906). The method 9 includes controlling the temperature in at least one area of an upper surface of the stage 90 for a predetermined period based on a distortion image or warpage of the wafer 12 calculated from the first plurality of local images (operation 907) For example, the distortion image or warpage of the wafer 12 can be adjusted by controlling the temperature at different areas of the wafer 12 based on the distortion image or warpage of the wafer 12 calculated from the first plurality of local images. If the distortion image or warpage at one area of the wafer 12 is high, the heating temperature on the one area of the wafer 12 can be decreased.

FIG. 9B is a schematic flowchart of an embodiment of a method 9a of manufacturing a semiconductor device of a wafer 12, in accordance with some embodiments of the present disclosure. The method 9 includes performing an exposure process on the photoresist on the wafer 12 and a post-exposure baking process on the wafer 12 (operation 908). The method 9 includes defining a pattern on the wafer 12 by removing a portion of the photoresist and performing a hard baking process on the wafer 12 (operation 909). The method 9 includes automatically capturing a second plurality of local images on the upper surface of the wafer 12 by the optical sensor unit 40 (operation 910). The method 9 includes controlling the temperature on the at least one area of the upper surface of the stage based on a distortion image or warpage of the wafer 12 calculated from the second plurality of local images (operation 911). For example, the distortion image or warpage of the wafer 12 can be adjusted by controlling the temperature at different areas of the wafer 12 based on the distortion image or warpage of the wafer 12 calculated from the second plurality of local images. If the distortion image or warpage at one area of the wafer 12 is high, the heating temperature in the one area of the wafer 12 can be decreased.

One aspect of the present disclosure provides a system for manufacturing a semiconductor device. The system includes a processor, a processing reaction chamber body, a stage, and a heater. The processing reaction chamber body is configured to maintain a low-pressure environment, the system being configured to deposit a film on a wafer disposed in the low-pressure environment. The stage is configured to support the wafer during deposition of the film. The heater is electrically coupled to the processor and configured to control the temperature of the wafer by the stage. The stage includes an upper surface in contact with the wafer, and wherein the stage includes a plurality of heating lines electrically coupled to the heater for controlling the temperature in at least one area of the upper surface of the stage.

One aspect of the present disclosure provides a system for manufacturing a semiconductor device. The system includes a processor, a processing reaction chamber body, and a stage. The processor is coupled to a non-transitory computer-readable medium storing computer-executable instructions. The processing reaction chamber body is configured to maintain a low-pressure environment within a space of the processing reaction chamber body. The stage is configured to hold a wafer disposed in the space of the processing reaction chamber body. The stage is electrically coupled to the processor and being configured to maintain the temperature of the wafer for a predetermined period. The temperature of an upper surface of the stage is controlled by a heater. The stage includes a plurality of heating lines for controlling the temperature in at least one area on the wafer disposed on the upper surface of the stage.

One aspect of the present disclosure provides a method for manufacturing a semiconductor device. The method includes providing a wafer, placing the wafer on a stage within a vacuum environment, depositing a film on the wafer, performing a photoresist process on the wafer, performing a soft bake process on the wafer to cure the photoresist, automatically capturing a plurality of local images on an upper surface of the wafer by an optical sensor unit; controlling the temperature in at least one area of an upper surface of the stage for a predetermined period based on a distortion image or warpage of the wafer calculated from the first plurality of local images, wherein the stage includes a plurality of heating lines for controlling the temperature in at least one area of the upper surface of the stage.

The embodiments of the present disclosure provide systems and methods for manufacturing a semiconductor device. The critical dimension (CD) uniformity of a wafer is affected since the baking temperatures in each area on the surface of the wafer are different. In addition, the local heating temperature and heating speed of each area on the surface of the wafer will affect the deformation results and the CD uniformity of the film on the wafer. The CD uniformity or deformation on the wafer can be adjusted by controlling the temperature in each area of the wafer.

An average value of the critical dimension (CD) in each area of the wafer can be adjusted by controlling the temperature at each heating point (such as controlling the temperature at one heating point). In addition, the distortion image or warpage of the wafer can be adjusted by controlling the temperature at each heating point (such as controlling the temperature at one heating point). For example, in order to increase an average value of the CD in the area of the wafer on a heating point, the heating temperature at the area of the heating point can be decreased for a predetermined period.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system for manufacturing a semiconductor device, the system comprising:
a processor;
a processing reaction chamber body configured to maintain a low-pressure environment, the system being configured to deposit a film on a wafer disposed in the low-pressure environment;
a stage for supporting the wafer during deposition of the film; and
a heater electrically coupled to the processor and being configured to control the temperature of the wafer by the stage;
wherein the stage includes an upper surface in contact with the wafer, and wherein the stage includes a plurality of heating lines electrically coupled to the heater for controlling the temperature in at least one area of the upper surface of the stage.

2. The system of claim 1, wherein the plurality of heating lines include a first plurality of heating lines extending along a first orientation and a second plurality of heating lines extending along a second orientation orthogonal to the first orientation from a top view.

3. The system of claim 2, wherein each of the first plurality of heating lines further includes a first plurality of heating points and wherein the temperature of each of the first plurality of heating points is controlled and maintained in a constant value by the heater for a predetermined period.

4. The system of claim 3, wherein each of the second plurality of heating lines further includes a second plurality of heating points, wherein each point of the second plurality of heating points respectively overlaps one point of the first plurality of heating points.

5. The system of claim 3, wherein each of the second plurality of heating lines further includes a second plurality of heating points, wherein each point of the second plurality of heating points is respectively located at an intersection between one of the second plurality of heating lines and the first plurality of heating lines.

6. The system of claim 3, wherein one of the first plurality of heating points is disposed on an edge of the upper surface of the stage from the top view.

7. The system of claim 2, wherein one point of the first plurality of heating points is maintained at a different temperature from another adjacent point of the first plurality of heating points for a predetermined period.

8. The system of claim 2, wherein one point of the first plurality of heating points is maintained at the same temperature as one adjacent point of the first plurality of heating points for a predetermined period.

9. The system of claim 1, wherein the plurality of heating lines include a first plurality of heating lines extending through a geometrical center of the upper surface of the stage, and each of the first plurality of heating lines further includes a first plurality of heating points and wherein the temperature of each of the first plurality of heating points is controlled and maintained in a constant value by the heater for a predetermined period.

10. The system of claim 9, wherein the plurality of heating lines include a third plurality of heating lines, each of the third plurality of heating lines includes a different circle diameter measured from the geometrical center of the upper surface of the stage.

11. The system of claim 10, wherein each of the third plurality of heating lines further includes a third plurality of heating points, wherein each point of the third plurality of heating points respectively overlaps one point of the first plurality of heating points.

12. The system of claim 1, wherein the stage is configured to electrostatically hold the wafer during deposition of the film and the stage further includes lifter pins configured to separate the wafer from the stage.

13. The system of claim 1, wherein the stage is configured to be moveable for rotation and vertically.
